(19) United States
(12) Patent Application Publication
(10) Pub. No.: US 2024/0426891 A1
(43) Pub. Date: Dec. 26, 2024

(54) HIGH-IMPEDANCE FAULT POSITIONING METHOD AND SYSTEM BASED ON SYNCHRONOUS LISSAJOUS CURVE CHARACTERISTICS

(71) Applicant: Shandong University, Jinan (CN)

(72) Inventors: Fang SHI, Jinan (CN); Hengxu ZHANG, Jinan (CN); Zhaoru HAN, Jinan (CN); Zongshuai JIN, Jinan (CN); Xiaobin WANG, Jinan (CN)

(73) Assignee: Shandong University, Jinan (CN)

(21) Appl. No.: 18/611,740

(22) Filed: Mar. 21, 2024

(30) Foreign Application Priority Data
Jun. 26, 2023 (CN) 202310752536.8

(51) Int. Cl. G01R 31/08

(52) U.S. Cl. CPC G01R 31/088; G01R 31/085

(57) ABSTRACT

A high-impedance fault positioning method and system based on synchronous Lissajous curve characteristics are provided. The method includes: acquiring a bus zero-sequence differential voltage and a feeder zero-sequence current of a faulty line; constructing a first Lissajous curve in a characteristic frequency band range based on the bus zero-sequence differential voltage and the feeder zero-sequence current; when the proportion of the faulty line is less than a set threshold value and the slope of the first Lissajous curve is negative, determining that high-impedance faults have occurred in the faulty line; constructing a second Lissajous curve based on the bus zero-sequence differential voltage and the section zero-sequence current, performing linear fitting on discrete data points of the second Lissajous curve to obtain a fitted curve; and when the slope of the fitted curve is negative for at least three consecutive periods, determining that high-impedance faults have occurred in the section.

### CROSS REFERENCE TO THE RELATED APPLICATIONS

This application is based upon and claims priority to Chinese Patent Application No. 202310752536.8, filed on Jun. 26, 2023, the entire contents of which are incorporated herein by reference.

### Technical Field

The present invention belongs to the field of high-impedance fault positioning of a power distribution network, and particularly relates to a high-impedance fault positioning method and system based on synchronous Lissajous curve characteristics.

### BACKGROUND

The statements in this section merely provide background information related to the present invention and do not necessarily constitute the prior art.

High-impedance faults (HIFs) of a power distribution network are commonly found in medium-voltage power distribution networks, and are dominated by single-phase ground faults, which account for about 5%-10% of medium-voltage distribution network faults. High-impedance faults are mostly caused by overhead lines being broken or drooping and coming into contact with non-metallic conductors such as cement ground, trees and lawns to form ground faults, and ground resistance is generally maintained to be hundreds of ohms to thousands of ohms. Generally, the surface of the ground medium is not smooth, and when a wire forms an electrical connection with the ground medium and causes a ground fault, it is accompanied by a nonlinear air-arc breakdown or solid medium breakdown, which is called arc high-impedance faults (AHIFs). So far, the detection precision for the arc high-impedance faults is still low, and the main reasons include the uncertain structure of a power distribution system, the complex feeder topology, the weak fault information, the serious arc nonlinearity, and the like. The arc high-impedance faults will pose significant safety hazards if they exist for a long period of time, triggering incidents such as personnel electric shock, equipment failure, and fire disasters. Accurate fault positioning is a necessary condition for realizing reliable isolation of arc high-impedance faults.

In the past studies, methods for detecting arc high-impedance faults are mainly classified into steady-state methods and transient methods. In methods such as an admittance method, an amplitude comparison method, and a steady-state power direction method, since characteristic quantities adopted by the detection algorithm depend on the system operating state and fault scenarios, and the steady-state electrical quantity after the occurrence of high-impedance faults is very small, the characteristic quantities are difficult to accurately extract due to PT, CT and analog-to-digital conversion errors. In methods such as a transient energy method, a transient power method, and a projection coefficient method, since the characteristics of the arc high-impedance faults are developmental, and the transition resistance is relatively high at the initial stage of the faults and even reaches more than ten thousand ohms, transient characteristics are submerged and cannot be effectively extracted by the existing measuring devices. For time distribution characteristics of the nonlinear presentation of arc high-impedance fault waveforms, time-frequency domain analysis methods such as wavelet transform, Hilbert-Huang transform, and Choi-Williams distribution are widely applied. However, such methods are implemented by extracting the high-frequency information of faulty arcs, and have poor anti-noise capacity.

The power distribution network mainly includes three forms of neutral grounding, resonant grounding, and small resistance grounding. In the resonant grounding system, the current direction of a faulty line of the resonant grounding system is uncertain due to the effect of the arc suppression coil, and the line selection and section positioning of the single-phase ground fault are relatively difficult to realize. In addition, the compensation degree of the arc suppression coil of the actual power distribution network can be adjusted according to the operation mode of the system, and the broadband characteristics of the ground fault of the resonant grounding system will be affected by the line length. These factors have little effect on the low-resistance fault positioning method, but cannot be ignored when dealing with high-impedance faults.

Based on the above factors, the conventional high-impedance fault positioning methods have blind spots and limitations in the practical application process.

### SUMMARY

In order to solve the technical problems such as the difficulty in high-impedance fault positioning of the resonant grounding system in the background described above, the present invention provides a high-impedance fault positioning method and system based on synchronous Lissajous curve characteristics, which can improve the accuracy of high-impedance fault positioning by constructing a first Lissajous curve for high-impedance fault positioning with few faulty lines, and by dividing faulty lines into different segments and utilizing a constructed second Lissajous curve for high-impedance fault positioning with many faulty lines and long faulty lines.

In order to achieve the above objective, the present invention adopts the following technical solutions:

The first aspect of the present invention provides a high-impedance fault positioning method based on synchronous Lissajous curve characteristics.

Provided is a high-impedance fault positioning method based on synchronous Lissajous curve characteristics, which includes:
acquiring a bus zero-sequence differential voltage and a feeder zero-sequence current of a faulty line;
constructing a first Lissajous curve in a characteristic frequency band range based on the bus zero-sequence differential voltage and the feeder zero-sequence current;
when the proportion of the faulty line is less than a set threshold value and the slope of the first Lissajous curve is negative, determining that a high-impedance fault has occurred in the faulty line;
when the proportion of the faulty line is greater than the set threshold value, dividing a topological line of a power distribution network into sections, and synchronously acquiring a section zero-sequence current of each of the sections;
constructing a second Lissajous curve based on the bus zero-sequence differential voltage and the section zero-sequence current, and performing linear fitting on discrete data points of the second Lissajous curve to obtain a fitted curve; and
when the slope of the fitted curve is negative for at least three consecutive periods, determining that a high-impedance fault has occurred in the section;
wherein in a resonant system, due to the action of an arc suppression coil, the direction of a faulty line zero-sequence current is uncertain; the current is a capacitative current when overcompensation occurs, and the current is an inductive current when under compensation occurs; if the action of the arc suppression coil can be ignored, a formula can be simplified as:

$$Δ {u}_{0 c} = \frac{1}{( {C}_{0 n} - {C}_{0 Σ} )} \cdot {i}_{0 n} = {k}_{n} \cdot {i}_{0 n} : ;$$

where Δu_{0c} represents the bus zero-sequence differential voltage, Cₒₙ represents an equivalent capacitance of the faulty line to ground, C_{0Σ} represents a total capacitance of the system to ground, i₀ₙ represents the faulty line zero-sequence current, and kₙ represents a linear relationship between the bus zero-sequence differential voltage and the faulty line zero-sequence current;
a synchronous Lissajous curve is obtained in combination with mathematical relationships and characteristic frequency band selection, specifically as follows:
under the action of power frequency, a relationship between an inductance of the arc suppression coil and a total capacitance of the system to ground is as follows:

$${w}_{0} {L}_{p} = \frac{1}{( 1 - v ) {w}_{0} {C}_{0 Σ}}$$

where w₀ represents an angular frequency of the power frequency, Lₚ represents a zero-sequence inductance of the arc suppression coil, C_{0Σ} represents the total capacitance of the system to ground, and v represents a detuning degree of the system, usually between −0.1 and 0.1;
the sum of currents of the other healthy lines: i_{0C}_{ₒₙ}−i_{0C}_{_{0Σ}} a current of the arc suppression coil: i_{0L}_{ₚ}; the amplitude ratio of any two current components at any non-power frequency is obtained as follows:

$$\{ \begin{matrix}{I}_{0 {fC}_{0 n}} - {I}_{0 {fC}_{0 Σ}} = {U}_{0 fc} \cdot {jw}_{f} ( {C}_{0 n} - {C}_{0 Σ} ) \\ {I}_{0 {L}_{p}} = \frac{{U}_{0 fc}}{{jw}_{f} {L}_{p}} : ; \\ \frac{{I}_{0 {fC}_{0 n}} - {I}_{0 {fC}_{0 Σ}}}{{I}_{0 {L}_{p}}} = {{w}_{f}}^{2} ( {C}_{0 Σ} - {C}_{0 n} ) {L}_{p} = \frac{{w}_{f}^{2} ( {C}_{0 Σ} - {C}_{0 n} )}{( 1 - v ) {w}_{0}^{2} {C}_{0 Σ}}\end{matrix}$$

characteristic frequency band selection and faulty section threshold value design are performed based on the formula described above, specifically as follows:
when the capacitance of the faulty line to ground can be ignored as compared to the total capacitance of the system to ground, a current ratio is about k_{w}=(w_{f}/w₀)²/(1−v), where k_{w} decreases with the decrease of v; when v=0.1, if w_{f}, is at least three times the angular frequency, k_{w} has a minimum value, and the effect of the arc suppression coil on the current of the faulty line can be approximately ignored; therefore, the lower limit of the characteristic frequency band is selected to be 150 Hz, and meanwhile, main harmonic components in the high-impedance fault are 3, 5, and 7 odd harmonics, and 350 Hz is selected as the upper limit of the characteristic frequency band;
an experiment is performed on the effect of different faulty line lengths on the synchronous Lissajous curve based on the selected characteristic frequency band, with analysis results as follows:
Cₙ represents the proportion of the faulty line, and when Cₙ varies in a range of 0-0.4, an inductive current component brought by the arc suppression coil can be ignored, and the synchronous Lissajous curve is approximately a straight line with a negative slope; when Cₙ varies in a range of 0.4-0.6, the synchronous Lissajous curve shows a nonlinear distortion, but still has a negative overall slope; when Cₙ varies in a range of 0.6-1.0, the synchronous Lissajous curve has an increased degree of nonlinearity, and approximately becomes a straight line with a positive slope after Cₙ is greater than 0.8, which loses characteristics of the faulty line.

Further, the section zero-sequence current of each of the sections and the bus zero-sequence differential voltage are synchronously acquired using a synchronous phasor measurement unit.

Further, the linear fitting is performed on the discrete data points of the second Lissajous curve by a least square method.

Further, the section zero-sequence current of the faulty section is the sum of a zero-sequence current of a faulty point and a zero-sequence current of the section to ground.

Further, the threshold value is [0.6, 0.8].

Further, the characteristic frequency band range is 150-350 Hz.

Provided is a high-impedance fault positioning system based on synchronous Lissajous curve characteristics, which includes:
a data acquisition module configured to: acquire a bus zero-sequence differential voltage and a feeder zero-sequence current of a faulty line;
a first Lissajous curve construction module configured to: construct a first Lissajous curve in a characteristic frequency band range based on the bus zero-sequence differential voltage and the feeder zero-sequence current;
a first fault positioning module configured to: when the proportion of the faulty line is less than a set threshold value and the slope of the first Lissajous curve is negative, determine that a high-impedance fault has occurred in the faulty line;
a section dividing module configured to: when the proportion of the faulty line is greater than the set threshold value, divide a topological line of a power distribution network into sections, and synchronously acquire a section zero-sequence current of each of the sections;
a second Lissajous curve construction module configured to: construct a second Lissajous curve based on the bus zero-sequence differential voltage and the section zero-sequence current, and perform linear fitting on discrete data points of the second Lissajous curve to obtain a fitted curve; and
a second fault positioning module configured to: when the slope of the fitted curve is negative for at least three consecutive periods, determine that a high-impedance fault has occurred in the section.

Further, the section zero-sequence current of each of the sections and the bus zero-sequence differential voltage are synchronously acquired using a synchronous phasor measurement unit.

Further, the linear fitting is performed on the discrete data points of the second Lissajous curve by a least square method.

Further, the section zero-sequence current of the faulty section is the sum of a zero-sequence current of a faulty point and a zero-sequence current of the section to ground.

Compared with the prior art, the present invention has the following beneficial effects.

In the present invention, by constructing a first Lissajous curve for high-impedance fault positioning with few faulty lines, and by dividing faulty lines into different sections and utilizing a constructed second Lissajous curve for high-impedance fault positioning with many faulty lines and long faulty lines, the accuracy of the high-impedance fault positioning can be improved.

In the present invention, by dividing a power distribution network into different sections according to the probability of zero-sequence currents of the sections, and by fitting the second Lissajous curve in combination with the least square method, the accuracy of high-impedance fault positioning is improved.

### BRIEF DESCRIPTION OF THE DRAWINGS

The drawings, which constitute a part of the present invention, are used to provide a further understanding of the present invention, and schematic embodiments of the present invention and their descriptions are used to illustrate the present invention and do not constitute an undue limitation of the present invention.

FIG. 1 is a schematic diagram showing the change in a Lissajous curve of a faulty line at a first moment before a single-phase ground fault occurs according to the present invention;

FIG. 2 is a schematic diagram showing the change in a Lissajous curve of a faulty line at a second moment before a single-phase ground fault occurs according to the present invention;

FIG. 3 is a schematic diagram showing the change in a transient-state Lissajous curve when a single-phase ground fault occurs according to the present invention;

FIG. 4 is a schematic diagram showing the change in a steady-state Lissajous curve of a faulty line at a first moment after a single-phase ground fault occurs according to the present invention;

FIG. 5 is a schematic diagram showing the change in a steady-state Lissajous curve of a faulty line at a second moment after a single-phase ground fault occurs according to the present invention;

FIG. 6 is a schematic diagram showing the change in a steady-state Lissajous curve of a faulty line at a third moment after a single-phase ground fault occurs according to the present invention;

FIG. 7 is a diagram showing a zero-sequence equivalent circuit of a high-impedance fault of a resonant grounding system according to the present invention;

FIG. 8 is a diagram showing the change in the amplitude ratio of current components in a frequency range of 50-550 Hz according to the present invention;

FIG. 9 is a diagram showing the change in the amplitude ratio of current components in a frequency range of 150-350 Hz according to the present invention;

FIGS. 10A and 10B are diagrams showing a full frequency band curve and a characteristic frequency band curve of a synchronous Lissajous curve according to the present invention; FIG. 10A is a diagram showing a full frequency band curve of a synchronous Lissajous curve according to the present invention; FIG. 10B is a diagram showing a characteristic frequency band curve of a synchronous Lissajous curve according to the present invention;

FIG. 11 is a schematic diagram showing the effect of the change in the faulty line on a synchronous Lissajous curve according to the present invention;

FIG. 12 is a diagram showing a typical power distribution network topology with three outlets according to the present invention;

FIG. 13 is a diagram showing the collected waveforms over 0.3 s of a zero-sequence current of each of the sections of a measured dry cement ground fault according to the present invention;

FIG. 14 is a diagram showing waveforms for a single period of a zero-sequence current of each of the sections of a measured dry cement ground fault according to the present invention;

FIG. 15 is a diagram showing a waveform of a characteristic quantity k of each of the sections of a measured dry cement ground fault according to the present invention;

FIG. 16 is a flow chart of a high-impedance fault positioning method based on synchronous Lissajous curve characteristics according to the present invention.

### DETAILED DESCRIPTION OF THE EMBODIMENTS

The present invention is further described below with reference to the drawings and embodiments.

It should be noted that the following detailed descriptions are all exemplary and are intended to provide further illustrations of the present invention. Unless otherwise indicated, all technical and scientific terms used herein have the same meaning as commonly understood by those of ordinary skill in the art to which the present invention belongs.

It should be noted that the terms used herein are for the purpose of describing specific embodiments only and are not intended to limit exemplary embodiments according to the present invention. As used herein, the singular form is also intended to include the plural form unless otherwise clearly indicated in the context. In addition, it should be understood that when the terms “comprise” and/or “include” are used in this specification, they indicate the presence of features, steps, operations, devices, components, and/or combinations thereof.

It should be noted that the flow charts and block diagrams in the drawings illustrate the architecture, functionality and operation of possible implementations of methods and systems according to various embodiments of the present disclosure. It should be noted that each block in the flow charts or the block diagrams can represent a module, a program segment or a part of a code, and the module, the program segment or the part of the code includes one or more executable instructions for implementing logical functions specified in various embodiments. It should also be noted that in some alternative implementations, the functions indicated in the blocks can be implemented in an order different from that indicated in the drawings. For example, two consecutively represented blocks can actually be executed substantially in parallel, or they can sometimes be executed in a reverse order, depending on the functions involved. It should also be noted that each block of the flow charts and/or the block diagrams, and combinations of blocks in the flow charts and/or the block diagrams, can be implemented by using a dedicated hardware-based system that executes a specified function or operation, or by using a combination of dedicated hardware and computer instructions.

### Embodiment I

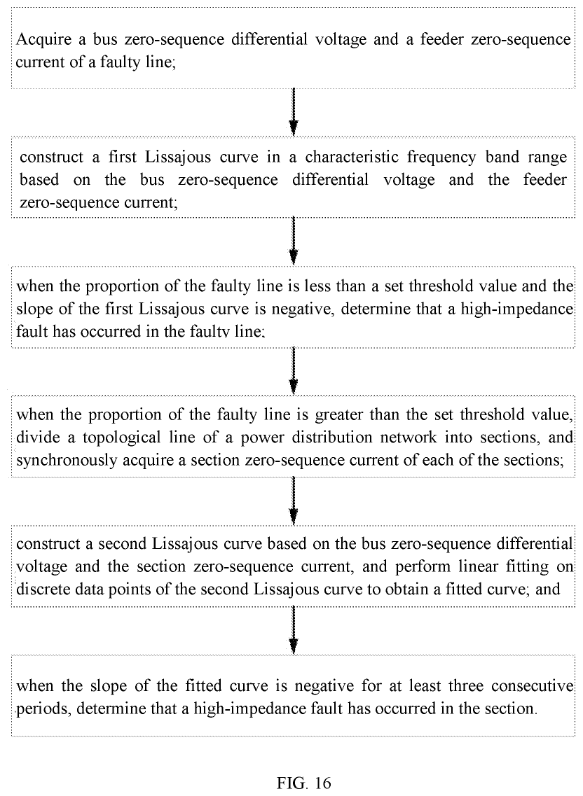

As shown in FIG. 16, this embodiment provides a high-impedance fault positioning method based on synchronous Lissajous curve characteristics. This embodiment is exemplified by applying the method to a server, and it can be understood that the method may also be applied to a terminal, or may also be applied to a system including the terminal and the server, and is implemented by interaction between the terminal and the server. The server may be an independent physical server, a server cluster or a distributed system formed by a plurality of physical servers, or a cloud server for providing basic cloud computing services such as a cloud service, a cloud database, cloud computing, a cloud function, cloud storage, a network server, cloud communication, a middleware service, a domain name service, security service CDN, and a big data and artificial intelligence platform. The terminal may be, but is not limited to, a smartphone, a tablet computer, a notebook computer, a desktop computer, and the like. The terminal and the server may be directly or indirectly connected through wired or wireless communication, which is not limited here by the present application. In this embodiment, the method includes the following steps:
acquiring a bus zero-sequence differential voltage and a feeder zero-sequence current of a faulty line;
constructing a first Lissajous curve in a characteristic frequency band range based on the bus zero-sequence differential voltage and the feeder zero-sequence current;
when the proportion of the faulty line is less than a set threshold value and the slope of the first Lissajous curve is negative, determining that a high-impedance fault has occurred in the faulty line;
when the proportion of the faulty line is greater than the set threshold value, dividing a topological line of a power distribution network into sections, and synchronously acquiring a section zero-sequence current of each of the sections;
constructing a second Lissajous curve based on the bus zero-sequence differential voltage and the section zero-sequence current, and performing linear fitting on discrete data points of the second Lissajous curve to obtain a fitted curve; and
when the slope of the fitted curve is negative for at least three consecutive periods, determining that a high-impedance fault has occurred in the section.

The inference procedure of fault positioning in this embodiment is described in detail below with reference to the drawings:

### (1) Synchronous Lissajous Curve

The standard Lissajous curve is formed by two sine waves superimposed in the vertical direction, and if the frequencies of the two sine waves are different or the phase difference between the two sine waves is different, various Lissajous curves are formed. In the electrical field, the current and voltage can be utilized to form a Lissajous curve. Under the normal operation of a power distribution network, the current and voltage are power frequency sine waves with a certain phase difference, and the formed Lissajous curve is an ellipse. After a fault occurs, the characteristics of the Lissajous curve such as the area size, the trajectory direction and the curvilinear distortion change, and the fault detection is carried out by utilizing the changes in the characteristics of the curve.

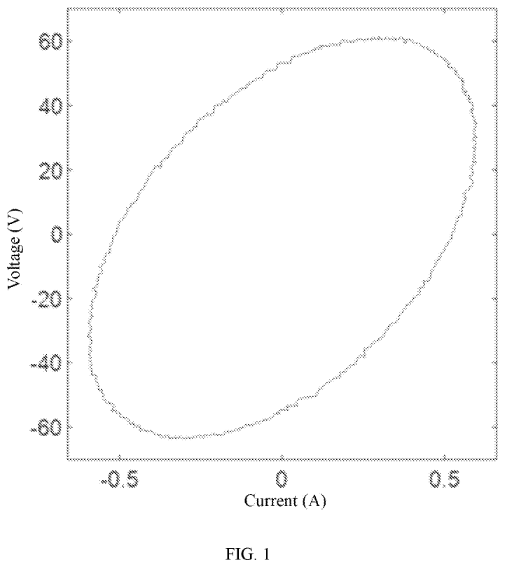

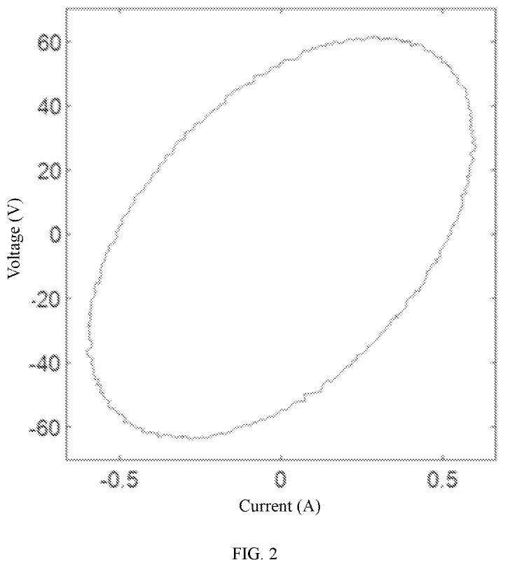

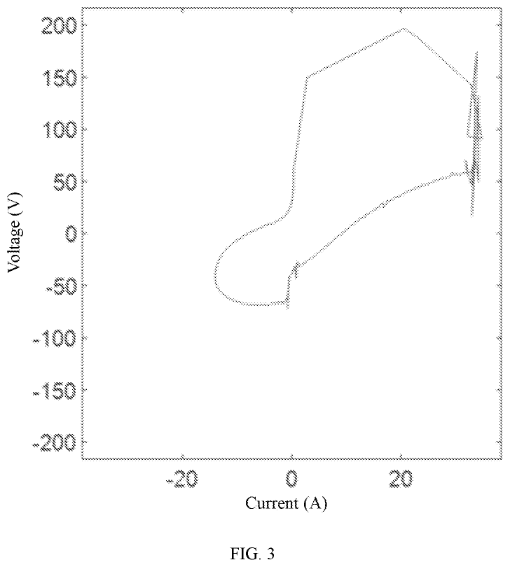

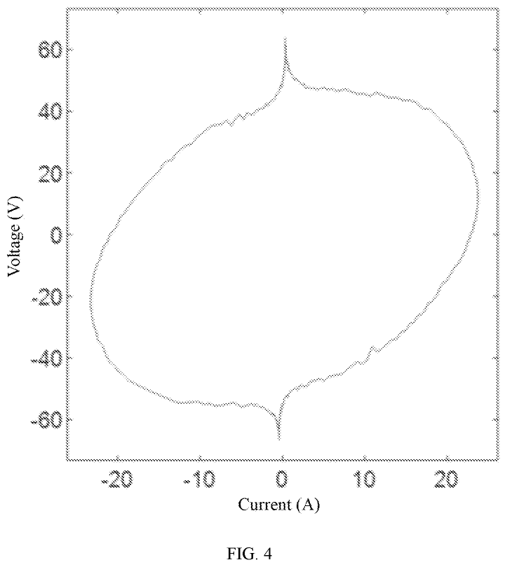

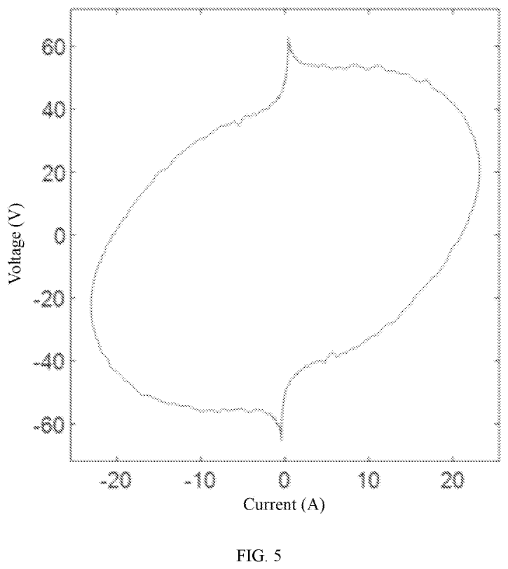

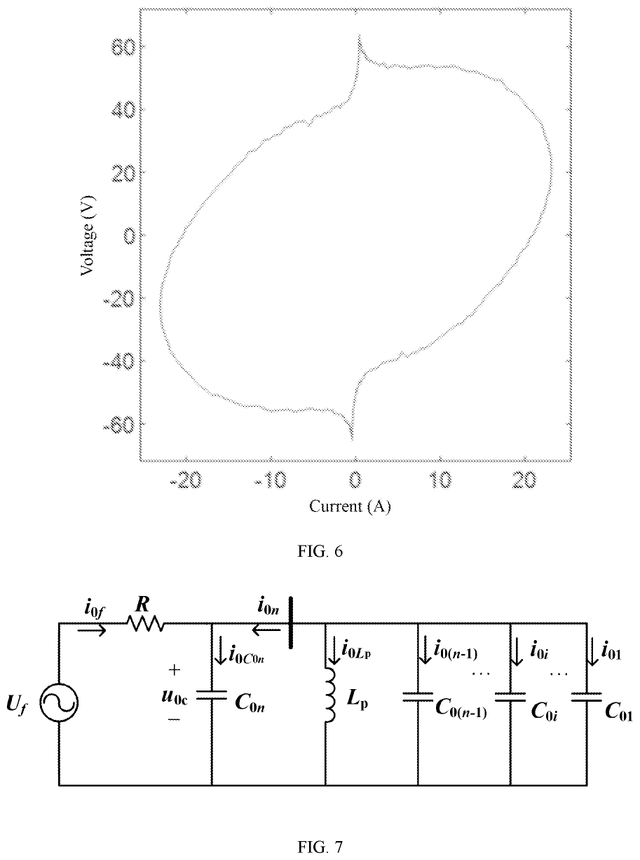

FIGS. 1-6 are schematic diagrams showing changes in Lissajous curves of a faulty line before and after a single-phase ground fault occurs. FIGS. 1 and 2 show Lissajous curves during normal operation of a power distribution network; FIG. 3 shows a transient-state Lissajous curve when a single-phase ground fault occurs; FIGS. 4, 5 and 6 show steady-state Lissajou curves after a fault occurs.

The conventional Lissajous curve has two significant disadvantages. Specifically, (1) fault detection is generally carried out based on the change in a characteristic threshold value, which has a good effect when dealing with low-resistance faults, but with the increase of transition resistance, the characteristic information is fuzzy, and the threshold value is difficult to set; (2) in a resonant grounding system, there is no clear differentiation between the characteristics of Lissajous curves of a healthy line (section) and a faulty line (section), and fault positioning cannot be realized. To solve the above problems, a synchronous Lissajous curve is obtained, the derivation process of which includes the following steps:

Step 1: a mathematical relationship between the bus zero-sequence differential voltage and the feeder zero-sequence current in a characteristic frequency band is analyzed in combination with a zero-sequence equivalent circuit.

FIG. 7 shows a zero-sequence equivalent circuit of a high-impedance fault of a resonant grounding system. R represents a triple fault resistance, Lₚ represents a zero-sequence inductance of an arc suppression coil, C₀ᵢ represents an equivalent capacitance of a healthy line to ground, and Cₙ represents an equivalent capacitance of a faulty line to ground.

By analyzing the zero-sequence equivalent circuit, the following mathematical relationship can be obtained.

The fault current i_{f0} is the sum of currents of all lines i_{0C}_{_{0Σ}} and a current flowing through the arc suppression coil i_{0L}_{ₚ}:

$${i}_{f 0} = {i}_{0 {C}_{0 Σ}} + {i}_{0 {L}_{p}} \qquad ( 1 )$$

The relationship between a healthy line current i₀ᵢ and a bus voltage u_{0c} is as follows:

$${i}_{0 i} = {i}_{0 {C}_{0 i}} = {C}_{0 i} \frac{{du}_{0 c}}{dt} \qquad ( 2 )$$

If the derivative of the bus voltage with respect to time is expressed in a differential form, the following relationships can be obtained:

$${i}_{0 i} = {C}_{0 i} \cdot Δ {u}_{0 c} \qquad ( 3 )$$

$$Δ {u}_{0 c} = \frac{1}{{C}_{0 i}} \cdot {i}_{0 i} = {k}_{i} \cdot {i}_{0 i} \qquad ( 4 )$$

where

$${k}_{i} = \frac{1}{{C}_{0 i}}$$

represents a linear relationship between a bus differential voltage where Δu_{oc} and a healthy line current i₀ᵢ.

Likewise, relationships between a faulty line current and the bus voltage are as follows:

$${i}_{0 n} = {i}_{0 {C}_{0 n}} - {i}_{0 f} = {i}_{0 {C}_{0 n}} - {i}_{0 {C}_{0 Σ}} - {i}_{0 {L}_{p}} = ( {C}_{0 n} - {C}_{0 Σ} ) Δ {u}_{0 c} - {i}_{0 {L}_{p}} \qquad ( 5 )$$

$$Δ {u}_{0 c} = \frac{1}{( {C}_{0 n} - {C}_{0 Σ} )} \cdot {i}_{0 n} + \frac{1}{( {C}_{0 n} - {C}_{0 Σ} )} \cdot {i}_{0 {L}_{p}} \qquad ( 6 )$$

In a resonant system, due to the action of an arc suppression coil, the direction of a zero-sequence current of a faulty line is uncertain; the current is a capacitative current when overcompensation occurs, and the current is an inductive current when undercompensation occurs. If the action of the arc suppression coil can be ignored, the formula (6) can be simplified as:

$$Δ {u}_{0 c} = \frac{1}{( {C}_{0 n} - {C}_{0 Σ} )} \cdot {i}_{0 n} = {k}_{n} \cdot {i}_{0 n} \qquad ( 7 )$$

Through the above derivation, the Lissajous curve of the healthy line formed by the zero-sequence current and the bus zero-sequence differential voltage is shaped like a straight line with a positive slope; if the effect of the arc suppression coil can be ignored by a certain method (such as characteristic frequency band extraction), the Lissajous curve of the faulty line formed by the zero-sequence current and the bus zero-sequence differential voltage is shaped like a straight line with a negative slope.

As can be seen from the mathematical relationships, there is a clear differentiation between the synchronous Lissajous curves of a healthy line and a faulty line, and the Lissajous curves are not affected by the size of the transition resistance, so they can be used to effectively detect high-impedance faults.

Step 2: a synchronous Lissajous curve is obtained in combination with mathematical relationships and characteristic frequency band selection.

Under the action of power frequency, a relationship between an inductance of the arc suppression coil and a total capacitance of the system to ground is as follows:

$${w}_{0} {L}_{p} = \frac{1}{( 1 - v ) {w}_{0} {C}_{0 Σ}} \qquad ( 8 )$$

where v represents a detuning degree of the system, usually between −0.1 and 0.1.

The current of the faulty line can be obtained by the formula (5), which consists of the following two parts: the sum of currents of the other healthy lines: i_{0C}_{₀ₙ}−i_{0C}_{_{0Σ}} and the current of the arc suppression coil: i_{0Lp}. The amplitude ratio of two current components at any non-power frequency is obtained as follows:

$$\{ \begin{matrix}{I}_{0 {fC}_{0 n}} - {I}_{0 {fC}_{0 Σ}} = {U}_{0 fc} \cdot {jw}_{f} ( {C}_{0 n} - {C}_{0 Σ} ) \\ {I}_{0 {L}_{p}} = \frac{{U}_{0 fc}}{{jw}_{f} {L}_{p}} \\ \frac{{I}_{0 {fC}_{0 n}} - {I}_{0 {fC}_{0 Σ}}}{{I}_{0 {L}_{p}}} = {{w}_{f}}^{2} ( {C}_{0 Σ} - {C}_{0 n} ) {L}_{p} = \frac{{w}_{f}^{2} ( {C}_{0 Σ} - {C}_{0 n} )}{( 1 - v ) {w}_{0}^{2} {C}_{0 Σ}}\end{matrix} \qquad ( 9 )$$

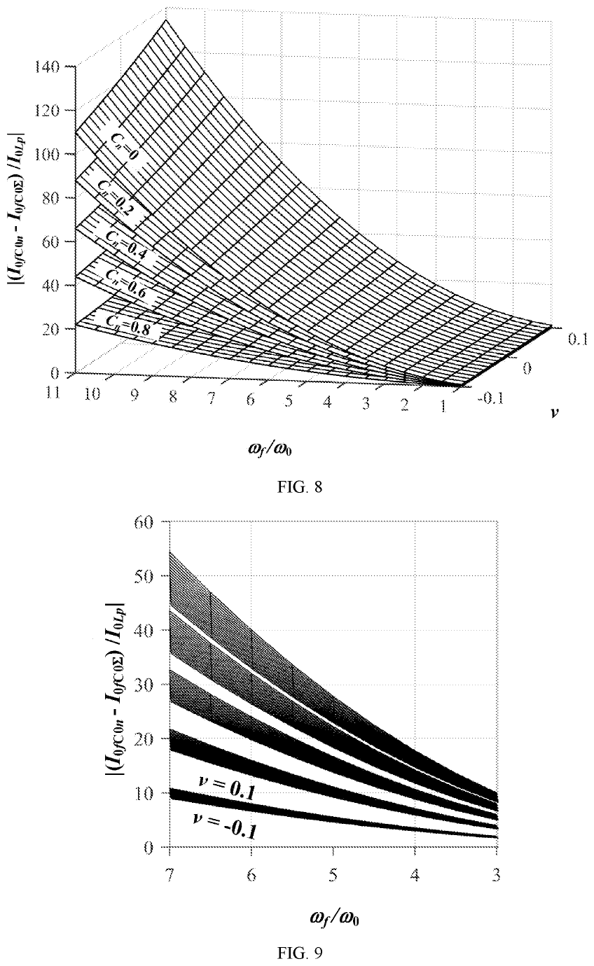

FIGS. 8 and 9 show the changes in the amplitude ratio of current components under different faulty line lengths (Cₙ represents the proportion of the faulty line), compensation degrees of the arc suppression coil, and non-power frequency crossover frequencies. A simplified analysis is first performed. When the capacitance of the faulty line to ground can be ignored as compared to the total capacitance of the system to ground, a current ratio is about k_{w}=(w_{f}w₀)²/(1−v), where k_{w} decreases with the decrease of V. When v=−0.1, if w_{f} is at least three times the power frequency, k_{w} has a minimum value of 8.18, and the effect of the arc suppression coil on the current of the faulty line can be approximately ignored.

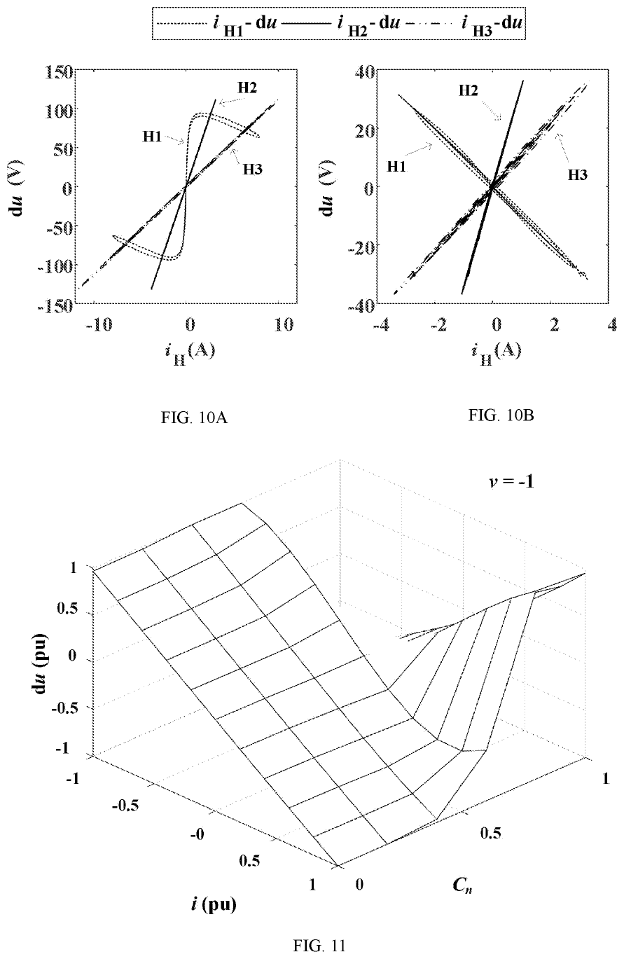

Therefore, the lower limit of the characteristic band is selected to be 150 Hz. Meanwhile, main harmonic components in the high-impedance fault are 3, 5, and 7 odd harmonics, and 350 Hz is selected as the upper limit of the characteristic frequency band. FIGS. 10A and 10B show synchronous Lissajous curves obtained under a full frequency band and a characteristic frequency band. FIG. 10A shows a synchronous Lissajous curve under a full frequency band, and FIG. 10B shows a synchronous Lissajous curve under a characteristic frequency band; wherein the horizontal axis represents a line zero-sequence current, and the vertical axis represents a bus zero-sequence differential voltage. H₁ represents a faulty line, and H₂ and H₃ represent healthy lines, which is consistent with the derivation results of the mathematical relationships.

### (2) Fault Positioning Method Based on Synchronous Lissajous Waveform Characteristics.

In the previous analysis, it is assumed that the capacitance of the faulty line to ground can be ignored as compared to the total capacitance of the system to ground. In fact, according to the results shown in FIG. 8, the current component brought by the arc suppression coil in the current of the faulty line cannot be ignored when the capacitance of the faulty line to ground increases. FIG. 11 shows the trend of change of the synchronous Lissajous curves obtained by experiments under different faulty line lengths at the characteristic frequency band [150 Hz, 350 Hz] when the compensation degree of the arc suppression coil is −1.

According to the results shown in FIG. 11, when Cₙ varies in a range of 0-0.4, an inductive current component brought by the arc suppression coil can be ignored, and the synchronous Lissajous curve is approximately a straight line with a negative slope; when Cₙ varies in a range of 0.4-0.6, the synchronous Lissajous curve shows a nonlinear distortion, but still has a negative overall slope; when Cₙ varies in a range of 0.6-1.0, the synchronous Lissajous curve has an increased degree of nonlinearity, and approximately becomes a straight line with a positive slope after Cₙ is greater than 0.8, which loses characteristics of the faulty line.

As can be seen from the analysis, when the faulty line Cₙ is less than 0.6, the line selection of the fault can be carried out by using a synchronous Lissajous curve. Generally, the feeder topology of the power distribution network is complex and has a plurality of feeders. This condition is met when a single-phase ground fault occurs. However, if an extreme case is considered, where only one power distribution line is provided and a measuring device is arranged at the head end, the further the faulty point is away from the bus, the greater the Cₙ is, and the method is in invalid in an extreme case.

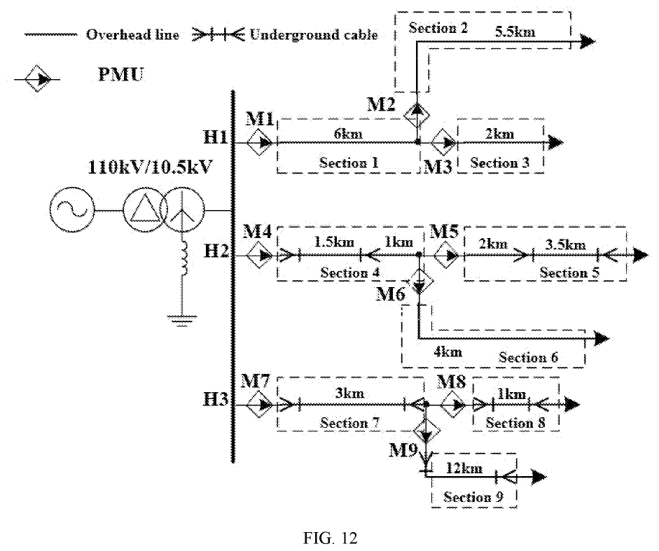

For the problem caused by the increase of the line length, a region surrounded by several measuring points can be called a section by the concept of “section zero-sequence current”, and the section current is a current obtained by subtracting the zero-sequence currents of all downstream measuring points from the zero-sequence currents of the upstream measuring points in the section. The section zero-sequence current of a healthy section is still a zero-sequence current to ground, while the section zero-sequence current of a faulty section is the sum of a zero-sequence current of a faulty point and a zero-sequence current of the section to ground (since one of the divided sections must contain the fault, a faulty current exists. In this embodiment, when the characteristic calculation is performed, the faulty current is not directly used, but is indirectly referenced by the zero-sequence current of the faulty section, and the section zero-sequence current of both a healthy section and a faulty section can be obtained by measurement calculation). At this time, Cₙ can be considered as the ratio of the capacitance of the section to ground to the total capacitance of the system. The effect of the line length on the characteristics of the faulty section can be significantly reduced by the section division processing of the line. As shown in FIG. 12, the system is divided into 9 sections by arranging measuring points. In order to ensure the precision, synchronous acquisition is required at the upstream and downstream of the section, a synchronous phasor measurement unit (PMU) can be used as a measuring device. The time synchronization error of the PMU is less than 1 microsecond, which meets the requirements of synchronous sampling.

Through the above processing, the synchronous Lissajous curves of the faulty section and the healthy section are approximately a straight line with a negative slope and a straight line with a positive slope, respectively. The linear fitting is performed on the discrete data points of the curve by a least square method, and the line positivity or negativity of the fitted straight line is determined for fault positioning.

The formula of the linear fitting by the least square method is as follows:

$$k = \frac{n {\sum }_{j = 1}^{n} {i}_{j} {u}_{j} - {\sum }_{j = 1}^{n} {i}_{j} {\sum }_{j = 1}^{n} {u}_{j}}{n {\sum }_{j = 1}^{n} {i}_{j}^{2} - {( {\sum }_{j = 1}^{n} {i}_{j} )}^{2}} \qquad ( 10 )$$

where n represents the number of sampling points over the time window, uⱼ, iⱼ represents a zero-sequence voltage and a zero-sequence current corresponding to each of the sampling points, and & represents the fitted slope.

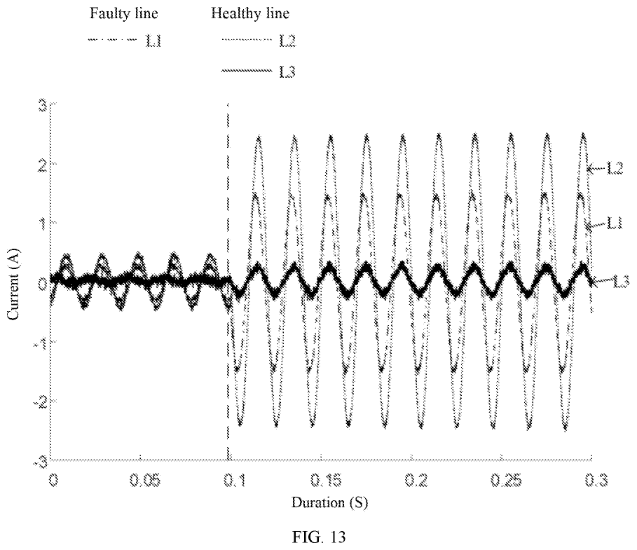

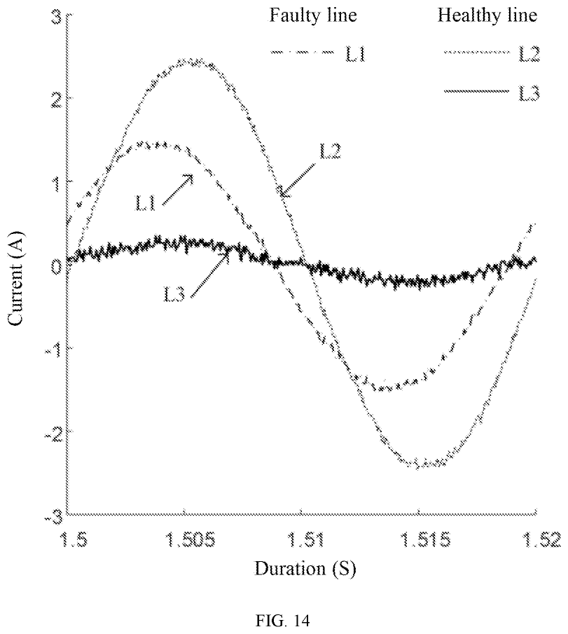

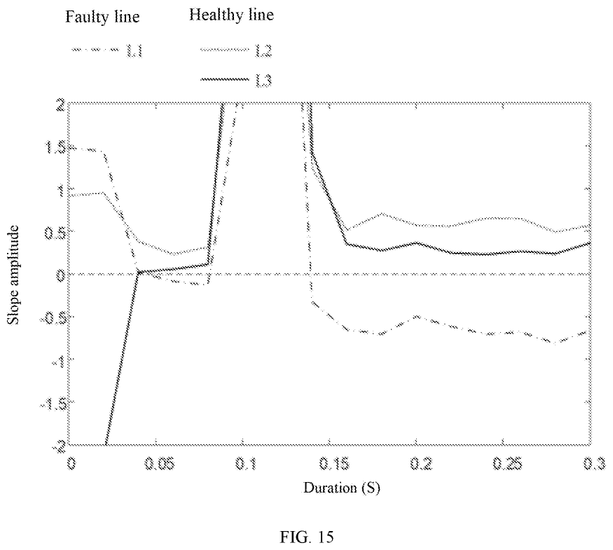

FIGS. 13, 14 and 15 show a group of high-impedance fault experiments in a 10 kV true testing ground. After a fault occurs, there is a clear differentiation between fault characteristics k of a faulty section and a healthy section. In order to realize effective fault positioning, it is provided that after detecting the occurrence of a fault, a certain section is considered as a faulty section when the fault characteristic k of the section is negative for three consecutive periods.

In the present invention, a synchronous Lissajous curve is derived in combination with a formula by analyzing an equivalent circuit of a high-impedance fault of a resonant grounding system. After the characteristic frequency band selection, there is a clear differentiation between the synchronous Lissajous curve characteristics of a faulty line (section) and a healthy line (section) proposed by the present invention, so that the line selection and section positioning of the fault can be simultaneously taken into account.

In the present invention, a mathematical relationship between the bus zero-sequence differential voltage and the feeder zero-sequence current under a characteristic frequency band is analyzed in combination with a zero-sequence equivalent circuit; the electrical quantities (voltage and current) of the power distribution network are visualized based on the principle of the Lissajous curve to analyze the differences in the characteristics of a healthy line (section) and a faulty line (section) of a high-impedance fault in the resonant grounding system.

In the present invention, the effect of different compensation degrees of the arc suppression coil and line changes on the proposed fault characteristics is analyzed, which is combined with the actual engineering scenario to facilitate the development and the practical application of the subsequent fault detection and positioning algorithm.

The present invention solves the problem that the conventional fault positioning methods have blind spots and limitations to a certain extent, and the characteristics and the method proposed by the present invention have no threshold setting, and get rid of the defect that the current mainstream method depends on transient characteristics at the initial stage of the fault. Theoretically, the proposed method is only limited by the precision of the measuring device, and is not affected by the type and the occurrence time of the fault, so that the fault characteristics can be continuously extracted and positioned as long as the high-impedance fault grounding state persists.

### Embodiment II

This embodiment provides a high-impedance fault positioning system based on synchronous Lissajous curve characteristics.

Provided is a high-impedance fault positioning system based on synchronous Lissajous curve characteristics, which includes:
a data acquisition module configured to: acquire a bus zero-sequence differential voltage and a feeder zero-sequence current of a faulty line;
a first Lissajous curve construction module configured to: construct a first Lissajous curve in a characteristic frequency band range based on the bus zero-sequence differential voltage and the feeder zero-sequence current;
a first fault positioning module configured to: when the proportion of the faulty line is less than a set threshold value and the slope of the first Lissajous curve is negative, determine that a high-impedance fault has occurred in the faulty line;
a section dividing module configured to: when the proportion of the faulty line is greater than the set threshold value, divide a topological line of a power distribution network into sections, and synchronously acquire a section zero-sequence current of each of the sections;
a second Lissajous curve construction module configured to: construct a second Lissajous curve based on the bus zero-sequence differential voltage and the section zero-sequence current, and perform linear fitting on discrete data points of the second Lissajous curve to obtain a fitted curve; and
a second fault positioning module configured to: when the slope of the fitted curve is negative for at least three consecutive periods, determine that a high-impedance fault has occurred in the section.

It should be noted here that the data acquisition module, the first Lissajous curve construction module, the first fault positioning module, the section dividing module, the second Lissajous curve construction module, and the second fault positioning module described above have the same examples and application scenarios as those realized by the steps in Embodiment I, but are not limited to the contents disclosed in Embodiment I described above. It should be noted that the modules described above as part of the system may be executed in a computer system such as a set of computer executable instructions.

The above descriptions are only preferred embodiments of the present invention and are not intended to limit the present invention, and various modifications and changes may be made to the present invention by those skilled in the art. Any modification, equivalent substitution, improvement, and the like made within the spirit and principle of the present invention shall all fall within the protection scope of the present invention.

What is claimed is:

1. A high-impedance fault positioning method based on synchronous Lissajous curve characteristics, comprising:
acquiring a bus zero-sequence differential voltage and a feeder zero-sequence current of a faulty line;
constructing a first Lissajous curve in a characteristic frequency band range based on the bus zero-sequence differential voltage and the feeder zero-sequence current of the faulty line;
when a proportion of the faulty line is less than a set threshold value and a slope of the first Lissajous curve is negative, determining that a high-impedance fault has occurred in the faulty line;
when the proportion of the faulty line is greater than the set threshold value, dividing a topological line of a power distribution network into sections, and synchronously acquiring a section zero-sequence current of each of the sections;
constructing a second Lissajous curve based on the bus zero-sequence differential voltage and the section zero-sequence current of each of the sections, and performing a linear fitting on discrete data points of the second Lissajous curve to obtain a fitted curve; and
when a slope of the fitted curve is negative for at least three consecutive periods, determining that the high-impedance fault has occurred in the section;
wherein in a resonant system, due to an action of an arc suppression coil, a direction of a faulty line zero-sequence current is uncertain; a current is a capacitative current when overcompensation occurs, and the current is an inductive current when undercompensation occurs; if the action of the arc suppression coil is ignored, a formula is simplified as:
$$Δ {u}_{0 c} = \frac{1}{( {C}_{0 n} - {C}_{0 Σ} )} \cdot {i}_{0 n} = {k}_{n} \cdot {i}_{0 n} : ;$$
wherein Δu_{0c} represents the bus zero-sequence differential voltage, C₀ₙ represents an equivalent capacitance of the faulty line to ground, C_{0Σ} represents a total capacitance of the resonant system to ground, i₀ₙ represents the faulty line zero-sequence current, and kₙ represents a linear relationship between the bus zero-sequence differential voltage and the faulty line zero-sequence current;
a synchronous Lissajous curve is obtained in combination with mathematical relationships and a characteristic frequency band selection, comprising:
under an action of a power frequency, a relationship between an inductance of the arc suppression coil and the total capacitance of the resonant system to ground is as follows:
$${w}_{0} {L}_{p} = \frac{1}{( 1 - v ) {w}_{0} {C}_{0 Σ}}$$
wherein w₀ represents an angular frequency of the power frequency, Lₚ represents a zero-sequence inductance of the arc suppression coil, C_{0Σ} represents the total capacitance of the resonant system to ground, and v represents a detuning degree of the resonant system, usually between −0.1 and 0.1;
sum of currents of other healthy lines: i_{0C}_{₀ₙ}-i_{0C}_{_{0Σ}}; a current of the arc suppression coil: i_{0Lp}; an amplitude ratio of any two current components at any non-power frequency is obtained as follows:
$$\{ \begin{matrix}{I}_{0 {fC}_{0 n}} - {I}_{0 {fC}_{0 Σ}} = {U}_{0 fc} \cdot {jw}_{f} ( {C}_{0 n} - {C}_{0 Σ} ) \\ {I}_{0 {L}_{p}} = \frac{{U}_{0 fc}}{{jw}_{f} {L}_{p}} : \\ \frac{{I}_{0 {fC}_{0 n}} - {I}_{0 {fC}_{0 Σ}}}{{I}_{0 {L}_{p}}} = {{w}_{f}}^{2} ( {C}_{0 Σ} - {C}_{0 n} ) {L}_{p} = \frac{{w}_{f}^{2} ( {C}_{0 Σ} - {C}_{0 n} )}{( 1 - v ) {w}_{0}^{2} {C}_{0 Σ}}\end{matrix}$$
the characteristic frequency band selection and faulty section threshold value design are performed based on a formula described above, comprising:
when the equivalent capacitance of the faulty line to ground is ignored as compared to the total capacitance of the resonant system to ground, a current ratio is about k_{w}=(w_{f}/w₀)²/(1−v), wherein k_{w}, decreases with a decrease of v; when v=−0.1, if w_{f} is at least three times the angular frequency, k_{w} has a minimum value, and an effect of the arc suppression coil on a current of the faulty line is approximately ignored; therefore, a lower limit of a characteristic frequency band is selected to be 150 Hz, and meanwhile, main harmonic components in the high-impedance fault are 3, 5, and 7 odd harmonics, and 350 Hz is selected as an upper limit of the characteristic frequency band;
an experiment is performed on an effect of different faulty line lengths on the synchronous Lissajous curve based on the characteristic frequency band, with analysis results as follows:
Cₙ represents the proportion of the faulty line, and when Cₙ varies in a range of 0-0.4, an inductive current component brought by the arc suppression coil is ignored, and the synchronous Lissajous curve is approximately a straight line with a negative slope; when Cₙ varies in a range of 0.4-0.6, the synchronous Lissajous curve shows a nonlinear distortion, but still has a negative overall slope; when Cₙ varies in a range of 0.6-1.0, the synchronous Lissajous curve has an increased degree of nonlinearity, and approximately becomes a straight line with a positive slope after Cₙ is greater than 0.8, and loses characteristics of the faulty line.

2. The high-impedance fault positioning method based on the synchronous Lissajous curve characteristics according to claim 1, wherein the section zero-sequence current of each of the sections and the bus zero-sequence differential voltage are synchronously acquired using a synchronous phasor measurement unit.

3. The high-impedance fault positioning method based on the synchronous Lissajous curve characteristics according to claim 1, wherein the linear fitting is performed on the discrete data points of the second Lissajous curve by a least square method.

4. The high-impedance fault positioning method based on the synchronous Lissajous curve characteristics according to claim 1, wherein a section zero-sequence current of a faulty section is a sum of a zero-sequence current of a faulty point and a zero-sequence current of the faulty section to ground.

5. The high-impedance fault positioning method based on the synchronous Lissajous curve characteristics according to claim 1, wherein the set threshold value is [0.6, 0.8].

6. The high-impedance fault positioning method based on the synchronous Lissajous curve characteristics according to claim 1, wherein the characteristic frequency band range is 150 Hz-350 Hz.

7. A high-impedance fault positioning system based on synchronous Lissajous curve characteristics, used for realizing the high-impedance fault positioning method based on the synchronous Lissajous curve characteristics according to claim 1, comprising:
a data acquisition module configured to: acquire the bus zero-sequence differential voltage and the feeder zero-sequence current of the faulty line;
a first Lissajous curve construction module configured to: construct the first Lissajous curve in the characteristic frequency band range based on the bus zero-sequence differential voltage and the feeder zero-sequence current of the faulty line;
a first fault positioning module configured to: when the proportion of the faulty line is less than the set threshold value and the slope of the first Lissajous curve is negative, determine that the high-impedance fault has occurred in the faulty line;
a section dividing module configured to: when the proportion of the faulty line is greater than the set threshold value, divide the topological line of the power distribution network into the sections, and synchronously acquire the section zero-sequence current of each of the sections;
a second Lissajous curve construction module configured to: construct the second Lissajous curve based on the bus zero-sequence differential voltage and the section zero-sequence current of each of the sections, and perform the linear fitting on the discrete data points of the second Lissajous curve to obtain the fitted curve; and
a second fault positioning module configured to: when the slope of the fitted curve is negative for at least the three consecutive periods, determine that the high-impedance fault has occurred in the section.

8. The high-impedance fault positioning system based on the synchronous Lissajous curve characteristics according to claim 7, wherein the section zero-sequence current of each of the sections and the bus zero-sequence differential voltage are synchronously acquired using a synchronous phasor measurement unit.

9. The high-impedance fault positioning system based on the synchronous Lissajous curve characteristics according to claim 7, wherein the linear fitting is performed on the discrete data points of the second Lissajous curve by a least square method.

10. The high-impedance fault positioning system based on the synchronous Lissajous curve characteristics according to claim 7, wherein a section zero-sequence current of a faulty section is a sum of a zero-sequence current of a faulty point and a zero-sequence current of the faulty section to ground.

11. The high-impedance fault positioning system based on the synchronous Lissajous curve characteristics according to claim 7, wherein the set threshold value is [0.6, 0.8].

12. The high-impedance fault positioning system based on the synchronous Lissajous curve characteristics according to claim 7, wherein the characteristic frequency band range is 150 Hz-350 Hz.
